(19) United States
(12) Patent Application Publication
(10) Pub. No.: US 2014/0162465 A1
(43) Pub. Date: Jun. 12, 2014

(54) PLASMA SHIELD SURFACE PROTECTION

(71) Applicants: SEMATECH, INC., Albany, NY (US); BOARD OF TRUSTEES OF THE UNIVERSITY OF ILLINOIS, Champaign, IL (US)

(72) Inventors: John R. SPORRE, Roanoke, IN (US); Vibhu JINDAL, Niskayuna, NY (US); David RUZIC, Pesotum, IL (US)

(73) Assignees: BOARD OF TRUSTEES OF THE UNIVERSITY OF ILLINOIS, Champaign, IL (US); SEMATECH, INC., Albany, NY (US)

(21) Appl. No.: 13/710,667

(22) Filed: Dec. 11, 2012

(51) Int. Cl. H01L 21/027

(52) U.S. Cl. CPC H01L 21/027
USPC 438/778; 118/723 R

(57) ABSTRACT

Apparatuses and methods are provided for electrostatically inhibiting particle contamination of a surface of a process structure, such as a mask or reticle. The apparatuses include a plasma-generating system configured to establish a plasma shield over the surface of the process structure. The plasma shield includes a plasma region and a plasma sheath over the surface of the process structure, with the plasma sheath being disposed, at least partially, adjacent to the surface of the process structure, between the plasma region and the surface of the process structure. The plasma shield facilitates negatively charging particles within the plasma shield, and electrostatically inhibits negatively-charged particle contamination of the surface of the process structure to be protected.

### BACKGROUND

This invention relates generally to semiconductor device fabrication, and more particularly, to inhibiting particle contamination of a surface of a process structure, such as a surface of a reticle, mask, mask blank, wafer, substrate, glass plate, etc.

The electronics industry continues to rely on advances in semiconductor technology to realize ever higher-functioning devices in more compact areas. For many applications, realizing higher-functioning devices requires integrating a larger and larger number of electronic devices onto a single wafer. As the number of electronic devices per area of wafer increases, the manufacturing processes become more intricate.

One of the process steps encountered in the fabrication of integrated circuits and other semiconductor devices is photolithography. Generally stated, photolithography includes selectively exposing a specially-prepared wafer surface to a source of radiation using a patterned template to create an etched surface layer. Typically, the patterned template is a reticle, which is a flat, glass plate that contains the patterns to be reproduced on the wafer.

The industry trend towards the production of integrated circuits that are smaller and/or of higher logic density necessitates ever smaller line widths. The resolution with which a pattern can be reproduced on the wafer surface depends, in part, on the wavelength of ultraviolet light used to project the pattern onto the surface of the photoresist-coated wafer. State-of-art photolithography tools use deep, ultraviolet light, with wavelengths of 193 nm, which allow minimum feature sizes on the order of 20 nm. Tools currently being developed use 13.5 nm extreme ultraviolet (EUV) light to permit resolution of features at sizes below 30 nm.

Extreme ultraviolet lithography (EUVL) is a significant departure from the deep, ultraviolet lithography currently in use today. All matter absorbs EUV radiation, and hence, EUV lithography takes place in a vacuum. The optical elements, including the photo-mask, make use of defect-free multi-layers, which act to reflect light by means of interlayer interference. With EUV, reflection from the patterned surface is used as opposed to transmission through the reticle characteristic of deep, ultraviolet light photolithography. The reflective photo-mask (reticle) employed in EUV photolithography is susceptible to contamination and damage to a greater degree than reticles used in conventional photolithography. This imposes heightened requirements on reticle handling and manufacturing destined for EUV photolithography use. For example, any particle contamination of the surface of the reticle could compromise the reticle to a degree sufficient to seriously affect the end product obtained from the use of such a reticle during processing.

### BRIEF SUMMARY

In one aspect, the shortcomings of the prior art are overcome and additional advantages are provided through the provision of an apparatus for inhibiting particle contamination of a surface of a process structure. The apparatus includes, for instance: a plasma-generating system configured to establish a plasma shield over the surface of the process structure to be protected; wherein the plasma shield comprises a plasma region and a plasma sheath over the surface of the process structure, the plasma sheath being disposed at least partially adjacent to the surface of the process structure, between the plasma region and the surface of the process structure, and wherein the plasma shield electrostatically inhibits negatively-charged particle contamination of the surface of the process structure to be protected.

In a further aspect, a method is provided which includes, for instance: inhibiting particle contamination of a surface of a process structure to be protected. The inhibiting includes: generating a plasma shield over the surface of the process structure, the plasma shield including a plasma region and a plasma sheath over the surface of the process structure, wherein the plasma sheath is disposed, at least partially, adjacent to the surface of the process structure, between the plasma region and the surface of the process structure, and wherein the plasma sheath facilitates negatively charging particles within the plasma shield, and electrostatically inhibits negatively-charged particle contamination of the surface of the process structure.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a schematic of one embodiment of a fabrication facility for fabricating a process structure, such as a mask, which facilitates (for instance) semiconductor device fabrication;

FIG. 1B is a partial elevational view of a chamber with a process structure disposed on a support structure therein, and having an upper surface susceptible to particle contamination, which is to be protected, in accordance with one or more aspects of the present invention;

FIG. 2A is a schematic of one embodiment of a plasma shield facilitating electrostatic inhibiting of particle contamination of a surface of interest of a process structure, in accordance with one or more aspects of the present invention;

FIG. 2B depicts the fabrication facility of FIG. 1A, with certain regions thereof identified (by way of example only) where one or more plasma shields may be advantageously provided to protect the surface of interest of the process structure, in accordance with one or more aspects of the present invention;

FIGS. 3A & 3B depict elevational and plan views, respectively, of one embodiment of a plasma-generating system establishing a localized plasma shield over the surface of the process structure to be protected, in accordance with one or more aspects of the present invention;

FIGS. 4A & 4B depict elevational and plan views, respectively, of another embodiment of a plasma-generating system, which includes a plasma-generating antenna structure comprising a plurality of gas vents that facilitate delivery of a gas used in localized generation of a plasma shield, in accordance with one or more aspects of the present invention;

FIGS. 5A & 5B depict elevational and plan views, respectively, of another embodiment of a plasma-generating system, wherein the plasma-generating antenna structure of the system comprises gas vents and is disposed, at least partially, in close proximity to and along the periphery of the surface of the process structure to be protected, in accordance with one or more aspects of the present invention;

FIGS. 6A & 6B depict elevational and plan views, respectively, of another embodiment of a plasma-generating system comprising a plasma-generating antenna structure which includes multiple plasma-generating coils, and/or multiple turns of one or more plasma-generating coils, in accordance with one or more aspects of the present invention;

FIGS. 7A & 7B depict elevational and plan views, respectively, of a further embodiment of a plasma-generating system, which includes a gas flow mechanism configured to facilitate establishing a plasma shield over the surface of the process structure to be protected, in accordance with one or more aspects of the present invention;

FIGS. 8A & 8B depict elevational and plan views, respectively, of another embodiment of a plasma-generating system comprising a plasma-confining mechanism which, in this embodiment, includes multiple permanent magnets that facilitate generating a plasma shield over the surface of the process structure to be protected, in accordance with one or more aspects of the present invention;

FIGS. 9A & 9B depict elevational and plan views, respectively, of a further embodiment of a plasma-generating system comprising a plasma-confining mechanism, which includes multiple electromagnets disposed to facilitate generating a plasma shield over the surface of the process structure to be protected, in accordance with one or more aspects of the present invention; and

FIG. 10 is a flowchart of one embodiment of a process for, at least in part, fabricating a process structure, which utilizes a plasma shield that inhibits particle contamination of the surface of interest of the process structure, in accordance with one or more aspects of the present invention.

### DETAILED DESCRIPTION

The present invention and various aspects and advantages of the invention are explained more fully with reference to the non-limiting embodiments illustrated in the accompanying drawings. Descriptions of well-known starting materials, processing techniques, components, and equipment, are omitted so as not to unnecessarily obscure the invention in detail. It should be understood, however, that the detailed description and examples presented, while indicating embodiments of the invention, are given be way of illustration only, and not by way of limitation. Various substitutions, modifications, and/or rearrangements within the spirit and/or scope of the underlying inventive concepts will be apparent to those skilled in the art from this disclosure.

As noted, the reflective photo-mask (reticle) employed in EUV photolithography is susceptible to contamination and damage to a greater degree than reticles used in conventional photolithography. This imposes heightened requirements on reticle handling and manufacturing destined for EUV photolithography use. For example, any particle contamination of the surface of interest of a reticle could compromise the reticle to a degree sufficient to seriously affect the end product obtained from the use of such a reticle during processing. Thus, addressed hereinbelow, in one aspect, is the issue of particle contamination during reticle fabrication.

Note that as used herein, “surface of interest” and “surface to be protected” are used interchangeably. Further, note that the surface of interest is described below as being a surface of a process structure. Generally stated, a “process structure” is used herein to mean any of a variety of structures, including a reticle, a mask, a mask blank, a wafer, a substrate, or a plate, such as a glass plate, etc. Also, as used herein, a “plasma shield” comprises a plasma or plasma region, and a plasma sheath. The plasma sheath (or Debye sheath or electrostatic sheath) is a layer of plasma which has a greater density of positive ions, and hence an overall positive charge, that balances an opposite negative charge on the surface of a material with which the plasma is in contact.

The present disclosure provides various apparatuses and methods for protecting a surface of interest by inhibiting particle contamination of the surface using a plasma shield. In one aspect, an apparatus is provided which includes a plasma-generating system configured to establish a plasma shield over a surface of a process structure to be protected. As noted, the plasma shield includes a plasma region and a plasma sheath over the surface of the process structure. The plasma sheath is disposed at least partially adjacent to or at the surface of the process structure to be protected, and between the plasma region and the surface of the process structure. The plasma shield facilitates negatively charging any particle contamination within the plasma shield, and electrostatically inhibits negatively-charged particles from reaching the surface of the process structure. Numerous embodiments of the plasma-generating system and use of such a plasma shield are disclosed and claimed herein.

Reference is made below to the drawings (which are not drawn to scale for ease of understanding), wherein the same reference numbers used throughout different figures designate the same or similar components.

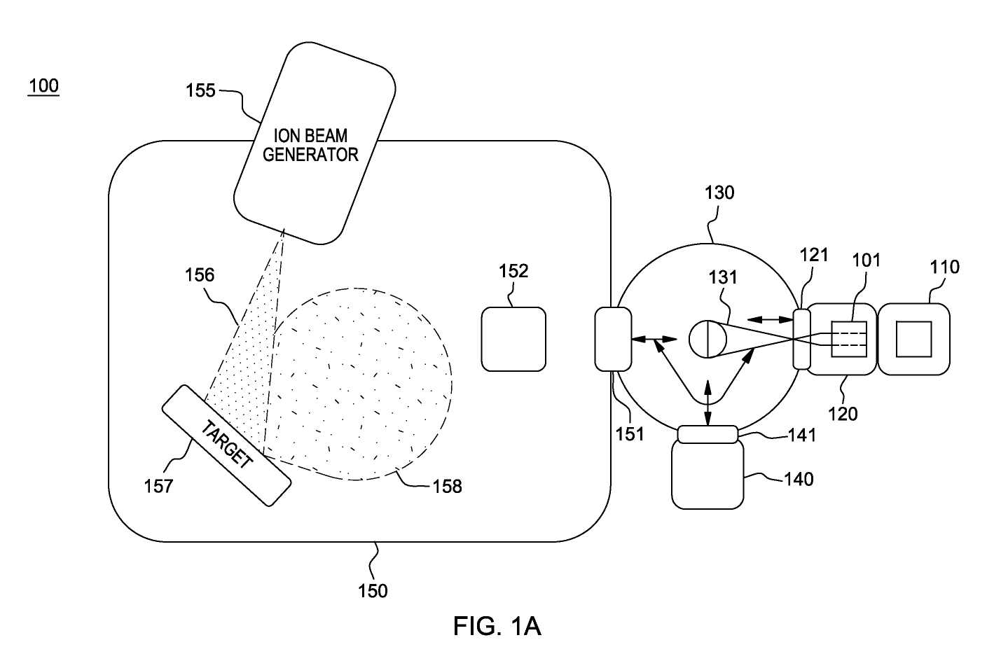

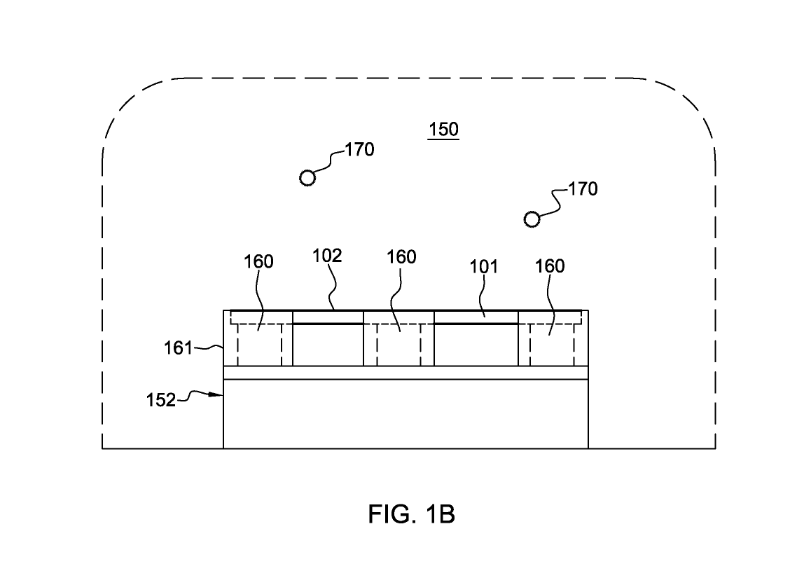

FIG. 1A depicts one embodiment of a fabrication facility, generally denoted 100, comprising multiple chambers employed in the fabrication of a process structure 101, such as an EUV mask. The multiple chambers include (by way of example) a holder chamber 110, a removal chamber 120, a robotic arm transfer chamber 130, a laser alignment chamber 140, and a deposition chamber 150. Process structure 101 is removed via a robotic arm 131 from holder chamber 110, through an isolation door 121 of removal chamber 120. Robotic arm 131 retracts the process structure 101 into the robotic arm transfer chamber 130, rotates the structure, and extends the structure into the laser alignment chamber 140, through an isolation door 141 of laser alignment chamber 140. In the laser alignment chamber, the robotic arm manipulates the location of the process structure to allow laser alignment to precisely identify where the process structure is located on the robotic arm in order that repeatable depositions may occur. The robotic arm 131 then repositions the process structure 101 at the vacuum isolation door 151 of deposition chamber 150. Vacuum isolation door 151 is opened, and process structure 101 is placed onto a support structure 152, which by way of example, may comprise a mechanical or electrostatic chuck. Once the support structure 152 is engaged to clamp or hold process structure 101, robotic arm 131 is retracted, and vacuum isolation door 151 is closed. Deposition chamber 150 conditions are set or manipulated for a desired deposition process and deposition processing proceeds, wherein multi-layer features may be deposited onto process structure 101. Specifically, by way of example, an ion beam generator 155 generates an ion beam 156, which impinges on a target 157, and results in a deposition plume 158 within process chamber 150. The deposition plume 158 is controlled so that the desired layer(s) is deposited onto process structure 101. After deposition is complete, support structure 152 (for example, electrostatic chuck) is disengaged, allowing the robotic arm 131 to remove process structure 101, and relocate the structure to the holder chamber 110.

One concern with the above-described process is the number of moving parts. Anything that moves within a semiconductor fabrication facility is likely to create particles, since the rubbing of two surfaces liberates particles anywhere from 10 s of nanometers to micrometers in size. In addition, within the deposition chamber, the support structure 152 may comprise an electrostatic chuck (or a mechanical chuck) used to restrain the process structure. With an electrostatic chuck, a charge may be induced within the process structure itself, which could electrostatically attract any oppositely-charged particles within the deposition chamber.

By way of example, FIG. 1B depicts process structure 101 disposed within deposition chamber 150, on an electrostatic chuck 160, surrounded (in part) by a shield 161. Surface 102 of interest of process structure 101 may become contaminated with particles 170 settling onto surface 102 within the chamber. Contaminant particles 170 may also inherently result from the deposition process as sputtering (i.e., material removal from a surface by incident-energetic ion/neutral atoms) is the operating procedure behind deposition. Particles can come from ion beam interaction with the target, as well as other surfaces inside the chamber. Furthermore, particles can be liberated from the walls of the chamber, for instance, by vibrations within the deposition chamber. The problem is exacerbated when employing an electrostatic chuck, wherein surface 102 of the process structure 101 may become slightly charged positive, and may attract oppositely-charged particles within the chamber.

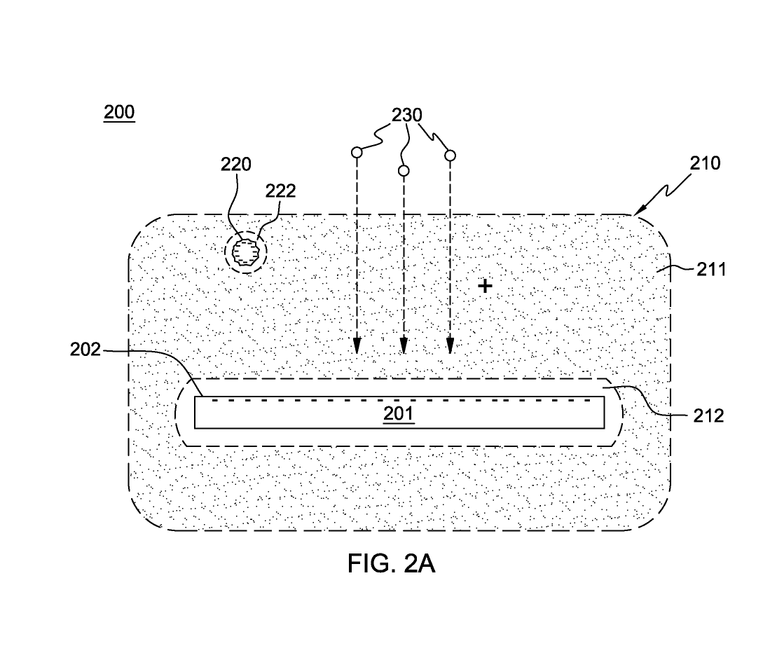

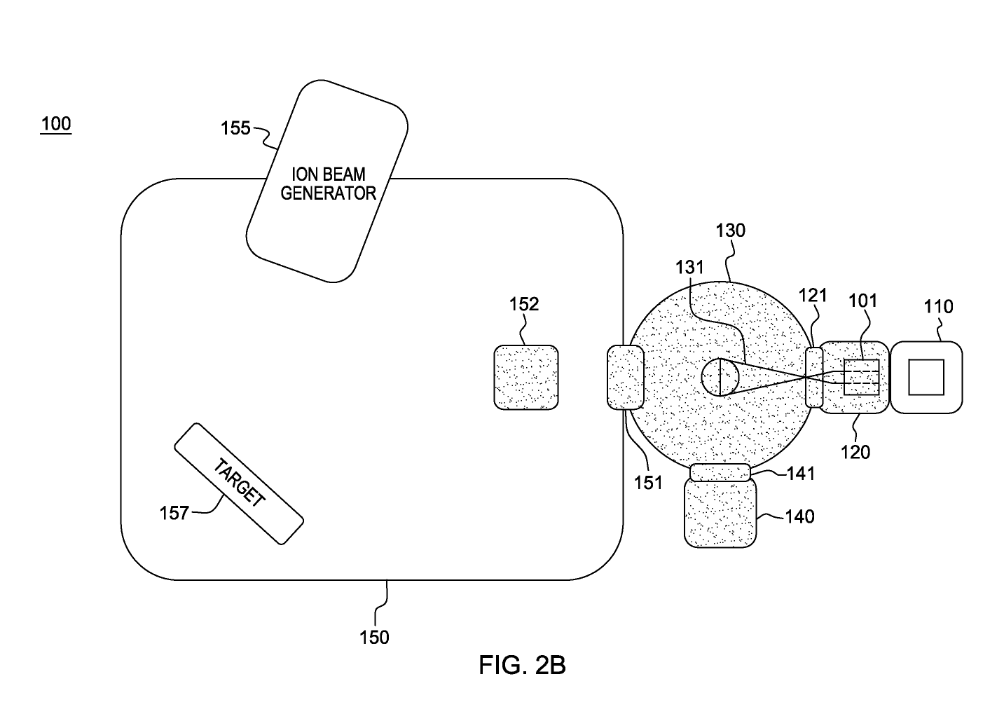

The solution disclosed herein is to generate a plasma shield, for instance, a localized plasma shield, around the process structure or the process structure and support structure (e.g., electrostatic chuck). This inventive solution is depicted in FIG. 2A, wherein a fabrication environment 200 is depicted, which includes a plasma shield 210 comprising a plasma region 211 and a plasma sheath 212. As illustrated, plasma sheath 212 is disposed at or adjacent to a surface 202 of interest of a process structure 201 to be protected. In the example depicted, plasma shield 210 surrounds process structure 201, as does plasma sheath 212. The plasma shield establishes an electric field, which is directed away from the surface 202 of interest of process structure 201. That is, there is a voltage different across the sheath, wherein process structure 201 is at a negative potential with respect to plasma region 211.

Similarly, a particle 220 within plasma shield 210, or more particularly, within plasma region 211, has a sheath 222 formed around the particle, and is also at a negative potential across sheath 222 with respect to plasma region 211. This voltage difference comes from electrons having much less mass than ions, and consequently, having a higher mobility. As is known, two negatively-charged surfaces repel one another, and so the negatively-charged particle 220 would not be able to reach negatively-charged surface 202, thereby inhibiting or preventing particle contamination of the surface of interest. Because of the low cross-section of interaction of the localized plasma shield 210, neutral atoms 230, e.g., the deposition species, are able to penetrate the plasma shield 210 without any issue, and become deposited on surface 202 of process structure 201. This allows the deposition process to proceed properly, while also facilitating protection of the process structure being fabricated.

As illustrated in FIG. 2B, the plasma shield concept could be extended for use within or throughout many of the chambers of the fabrication facility, for instance, while the process structure is being moved into or out of a chamber, or between chambers, or is being manipulated or deposited within a chamber. Also, a plasma shield could be implemented, in one embodiment, in association with the rotating robotic arm 131 that relocates the process structure from the mobile containment holder to the laser alignment chamber 140, as well as to the support structure 152 (e.g., electrostatic chuck) inside deposition chamber 150. Thus, the plasma-generating systems and concepts disclosed herein could be readily adapted to use within the different chambers, and/or for use in combination with the robotic arm. Generally stated, in one aspect, disclosed herein is the concept of a plasma shield around the surface of the process structure to be protected, and that this plasma shield provides protection against surface particle contamination by facilitating negative charging of particles within the plasma shield, and electrostatic inhibiting of negatively-charged particle contamination from reaching the surface of the process structure to be protected. Depending on the implementation, multiple plasma-generating systems or mechanisms may be employed within a fabrication facility, for instance, in association with different chambers of the facility, or in association with the robotic arm, and one or more chambers of the facility.

There are many different ways to create a plasma, but plasma characteristics are determined by, for instance, chamber geometry, plasma-generating parameters (power, wavelength frequency), chamber pressure, and chamber gas concentration or flow rate. As such, there are a variety of possible applications for the plasma shield concept disclosed herein. For instance, robotic arm 131 could be equipped with a radio frequency (RF) radiating antenna to assist in generating a localized plasma about the robotic arm. It would also be possible to generate a plasma in each of the chambers, independent of the location of the process structure. A uniform plasma throughout a chamber (for instance, made possible by manipulating the chamber pressure, and plasma-generating antenna structure design) would protect the process structure equally as well as a plasma shield generated locally to the process structure.

One common feature of the apparatuses and methods disclosed herein is that the process structure, and in particular, the surface to be protected of the process structure, is immersed in the plasma so that it, and any particles within the plasma, will be charged negative. As noted above, the concept is particularly advantageous in combination with the use of an electrostatic chuck (for instance, within a deposition chamber), because that is a location where significant particle contamination typically occurs. The electrostatic clamping forces of the electrostatic chuck may cause a biasing of the process structure, which can attract particles to its surface. Without a protective particle shield, these particles land on the surface, potentially ruining any deposited layers on the surface.

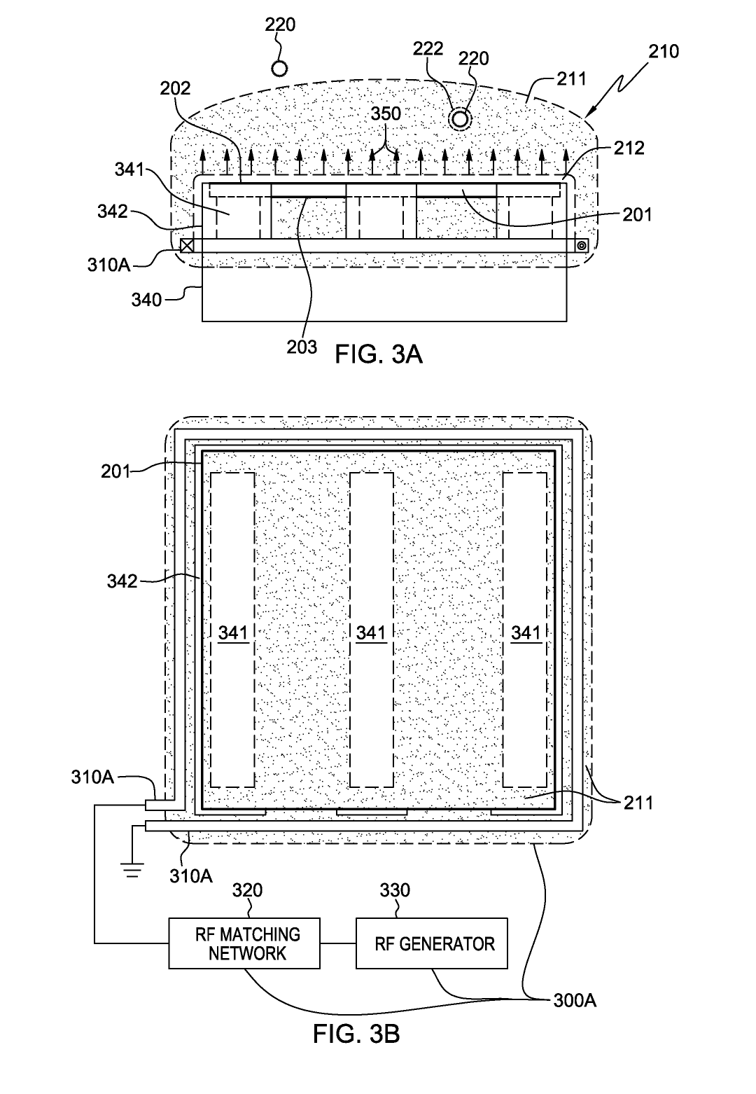

FIGS. 3A-9B depict various apparatuses and plasma-generating systems for establishing a plasma shield over a surface to be protected of a process structure. The examples given in these figures discuss, by way of example only, establishing of the plasma shield within a deposition chamber, with the process structure positioned on a support structure comprising an electrostatic chuck support. As noted above, however, the plasma shield concept could be readily adapted to use within other chambers of the fabrication facility, including the transfer chamber, or other support structures, such as a mechanical chuck or a robotic arm.

FIGS. 3A & 3B depict one embodiment of an apparatus and method for protecting a process structure, such as an EUV mask, from particle contamination utilizing a plasma shield during (for instance) clamping, deposition, and de-clamping of the process structure from, for instance, an electrostatic chuck, generally denoted 340. Note that the plasma shield could be maintained during the deposition process, or alternatively, removed during deposition, and then reestablished after deposition, depending upon the processes involved. As noted, plasma shield 210 results in creating a negative potential at the surface 202 of interest of process structure 201, due to the relatively high mobility of electrons versus positively-charged ions. Similarly, any particles 220 within plasma shield 210 become negatively-charged, relative to the plasma region 211 across a plasma sheath 222. An electrostatic force or potential 350 exists across the plasma sheath 212, which inhibits (or disallows) the deposition of the negatively-charged particles 220 onto surface 202 of the process structure 201.

More particularly, and referring collectively to FIGS. 3A & 3B, one embodiment of a plasma-generating system 300A is depicted. This plasma-generating system 300A is configured, positioned and connected to establish plasma shield 210 over surface 202 of interest of process structure 201. As described above, plasma shield 210 includes plasma region 211 and a plasma sheath 212 disposed between the surface 202 of interest and the plasma region 211. An electric field (or voltage difference) 350 is established across plasma sheath 212, with the plasma region 211 being more positively-charged than the negatively-charged surface 202 of the process structure 201 to be protected. This voltage difference prevents any negatively-charged particles (such as dust particles) 220 within plasma region 211 from reaching the surface 202. As noted, particles 220 within plasma shield 211 become negatively-charged, and the voltage difference (or electrostatic force) 350 ensures that the negatively-charged particles are directed away from the surface 202 of interest.

In the embodiment of FIGS. 3A & 3B, process structure 201 resides on support structure 340, which as noted, comprises (in one aspect) an electrostatic chuck support. The chuck support includes electrostatic clamps 341 that hold process structure 201 in fixed position within the deposition chamber. A physical particle shield 342 may also at least partially encircle the process structure 201, when held by support structure 340.

The plasma-generating system 300A includes, in the depicted embodiment, a plasma-generating antenna structure 310A, such as a radio frequency (RF) coil, disposed (at least partially) around a periphery of surface 202 of the process structure 201 to be protected. The plasma-generating system 300A further includes an RF matching network 320, and an RF generator 330, which are electrically coupled to plasma-generating antenna structure 310A, for instance, to one end thereof, with the other end being grounded. The conditions needed to generate and maintain a plasma are well known, as is a typical RF matching network and RF generator for a plasma-generating system, which could be employed in combination with the concepts disclosed herein. In one example, the plasma is generated in the presence of a gas, such as argon, helium, hydrogen or oxygen.

As noted, in the plasma-generating system 300A of FIGS. 3A & 3B, the plasma-generating antenna structure 310A extends along and around the periphery of surface 202 to be protected of process structure 201. In the elevation view of FIG. 3A, antenna structure 310A is shown disposed (by way of example) below process structure 201. This positioning may assist in inhibiting, for instance, any deposition build-up on the antenna structure from becoming dislodged and contaminating surface 202 of the process structure 201. In one specific implementation, antenna structure 310A could be fabricated of a same material as the material being deposited onto surface 202. For instance, the antenna structure could be manufactured of molybdenum in the case where a multi-layer UV mask is being fabricated within the deposition chamber, with alternating layers of, for example, silicon and molybdenum.

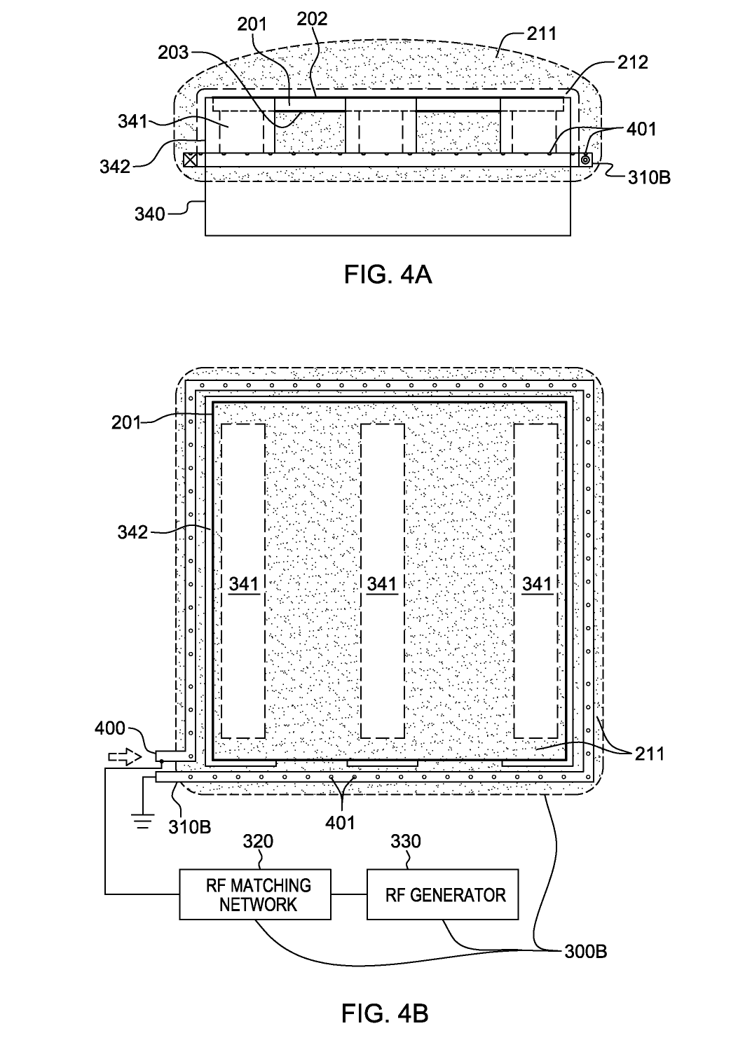

As noted, FIGS. 4A-9B depict, by way of further example, certain variations on the plasma-generating system discussed above, which may advantageously facilitate generating a plasma shield, and particularly, a localized plasma shield, within a chamber, such as a deposition chamber.

In the apparatus embodiment of FIGS. 4A & 4B, the plasma-generating system 300B is shown to include a plasma-generating antenna structure 310B that is configured and disposed similar to the antenna structure 310A described above in connection with FIGS. 3A & 3B. However, this antenna structure 310B is (for instance) tubular in nature, and has a gas inlet 400 and a plurality of gas vents 401. The gas vents 401 are disposed, at least partially, along the plasma-generating antenna structure 310B and are configured and positioned to facilitate injection or delivery of an inert gas to the region of the process structure 201 to assist in generation of a localized plasma shield 210 about process structure 201. As noted above, this inert gas could comprise, for instance, argon, or helium.

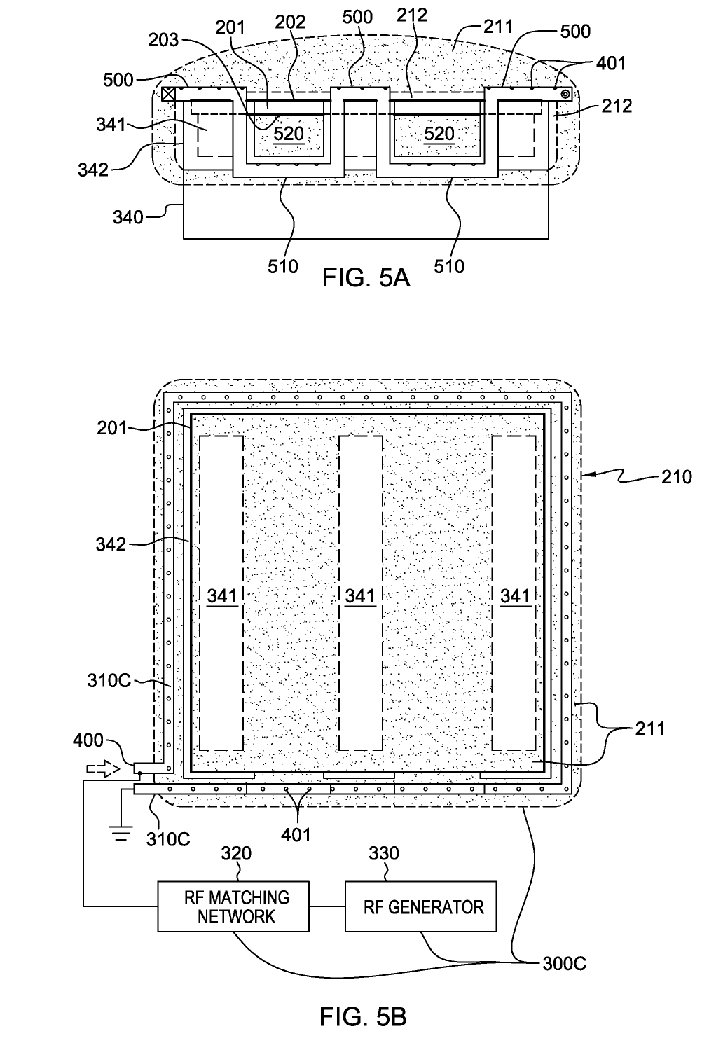

FIGS. 5A & 5B depict a further plasma-generating system 300C. In this embodiment, plasma-generating system 300C is shown to comprise a plasma-generating antenna structure 310C, with a three-dimensional configuration. As illustrated, a portion 500 of plasma-generating antenna structure 310C surrounds the periphery of surface 202 of process structure 201, and resides at, or even above, the surface of the process structure. One or more second portions 510 of the plasma-generating antenna structure 310C are also provided, which drop below openings 520 in physical particle shield 342. These portions drop down to allow the robotic arm (not shown) to extend into and engage the process structure, for instance, when transferring the process structure between chambers. This configuration may be beneficial in that it can deliver the inert gas for the plasma shield more closely or localized to the process structure, and thereby may facilitate forming a localized plasma shield over and around the process structure (and, if desired, around the support structure).

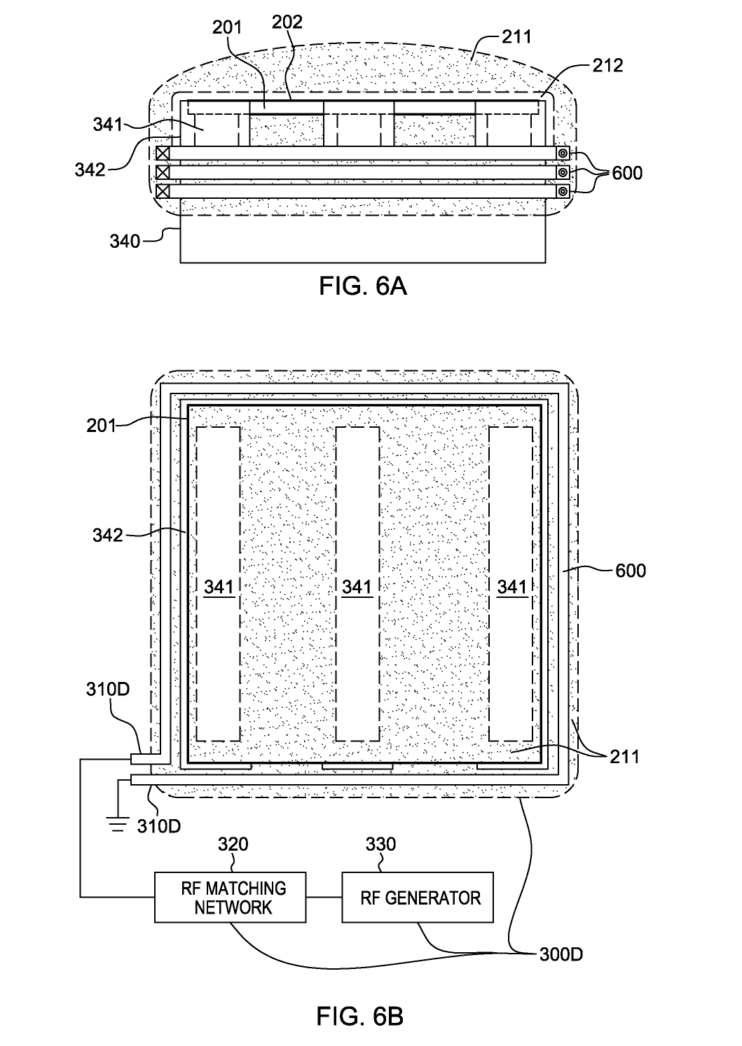

FIGS. 6A & 6B depict a further plasma-generating system 300D configuration, wherein the plasma-generating antenna structure 310D comprises multiple coil turns 600 of a single plasma-generating antenna structure or multiple coils 600 of multiple plasma-generating antenna structures. Assuming that the plasma-generating structure 310D comprises multiple separate coils 600 or antenna structures, then each antenna structure could (depending on the implementation) be individually controlled with its own, respective RF matching network 320 and RF generator 330. As a further variation, note that the plurality of gas vents in the embodiments of FIGS. 4A-5B could also be provided in one or more of the coils 600 of this embodiment.

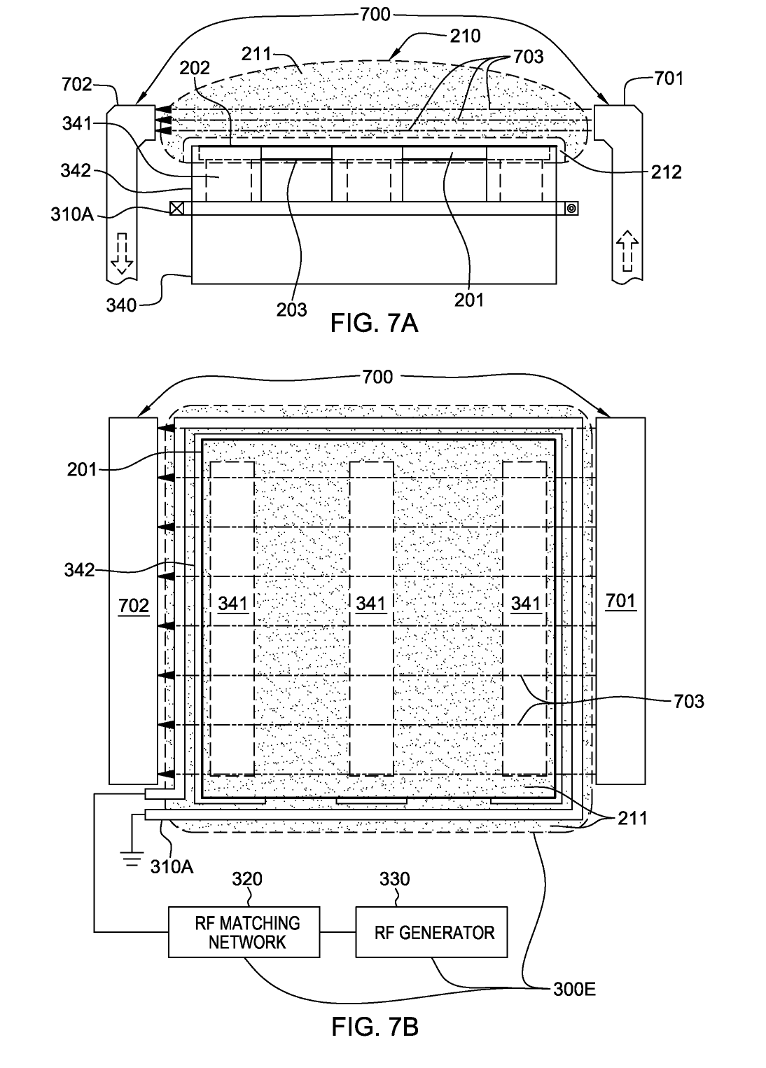

FIGS. 7A & 7B depict a further plasma-generating system 300E implementation, which comprises (by way of example) a plasma-generating antenna structure 310A, such as described above in connection with FIGS. 3A & 3B. To facilitate generation of plasma shield 210, this embodiment further includes a gas flow mechanism 700, which includes a gas injector 701 and a gas remover 702, disposed on opposite sides of process structure 201. As illustrated, gas flow mechanism 700 establishes, in one embodiment, a gas flow 703 above and across surface 202 of interest of process structure 201. This gas flow 703 may comprise, for instance, an inert gas curtain established between gas injector 701 and gas remover 702. The gas flow 703 may be a higher concentration gas, chosen and designed to facilitate formation of plasma shield 210. Additionally, the gas flow 703 over surface 202 of process structure 201 may facilitate entrapment and removal of dust particles from the region over the surface 201 of the process structure. Note that this concept could be combined with any of the antenna structure implementations described above in association with FIGS. 4A-6B.

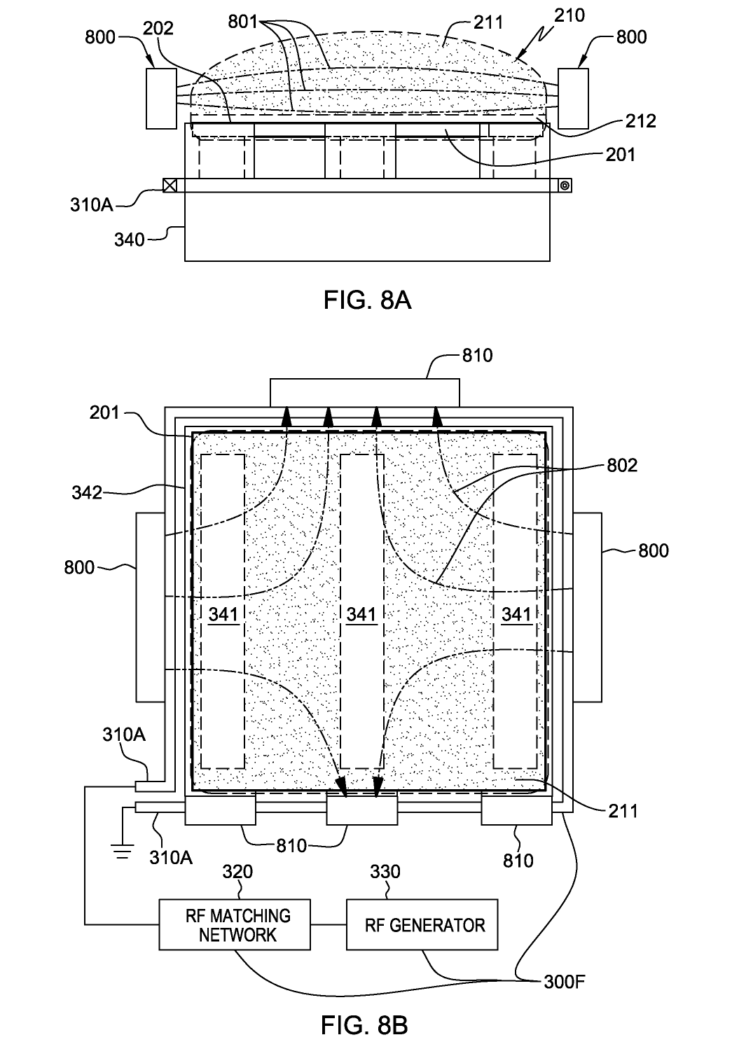

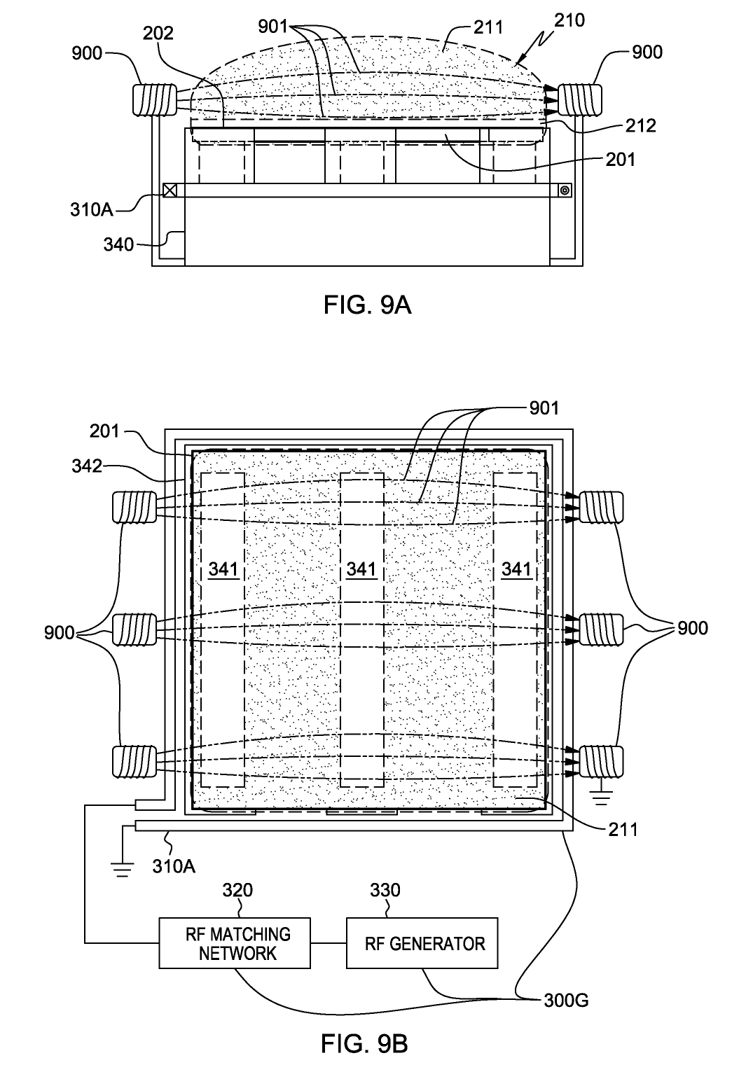

FIGS. 8A-9B depict further alternate plasma-generating system embodiments, wherein a magnetic-based, plasma-confining mechanism is provided. These plasma-confining mechanisms facilitate generating a plasma shield 210 over the surface 202 of the process structure 201 to be protected.

In the embodiment of FIGS. 8A & 8B, a plasma-generating system 300F is provided which includes a plasma-confining mechanism that comprises multiple permanent magnets 800 (FIG. 8A) or 800, 810 (FIG. 8B) disposed adjacent to the periphery of surface 202 of process structure 201, for instance, over or offset from plasma-generating antenna structure 310A, as depicted. Note that in the embodiment of FIG. 8A, straight field lines 801 are illustrated between two permanent magnets 800 disposed on opposite edges of process structure 201, while in the embodiment of FIG. 8B, additional permanent magnets 810 are added so that curved magnetic field lines 802 are established across surface 201 of the process structure 202. The purpose of the plasma-confining mechanisms, and the magnets in particular, is to entrain electrons in the region over surface 202 of interest of process structure 201 and thereby facilitate generation of plasma shield 210 over surface 202. Note that either of these plasma-confining mechanism implementations could be employed in combination with any of the above-discussed, plasma-generating system variations of FIGS. 4A-7B.

FIGS. 9A & 9B depict a further plasma-generating system 300G comprising another embodiment of a plasma-confining mechanism, in accordance with one or more aspects of the present invention. In this embodiment, multiple electromagnets 900 are disposed on opposite edges of surface 201 to be protected, with an electromagnetic field 901 being established between the electromagnets 900. This electromagnetic field 901 assists in confining electrons to the region over surface 201 of the process structure 202 to be protected, and thereby assists in generating plasma shield 210 over surface 202 of the process structure. Note that plasma-generating system 300G depicted in FIGS. 9A & 9B could also be modified to include any of the enhancements discussed above in connection with FIGS. 4A-7B.

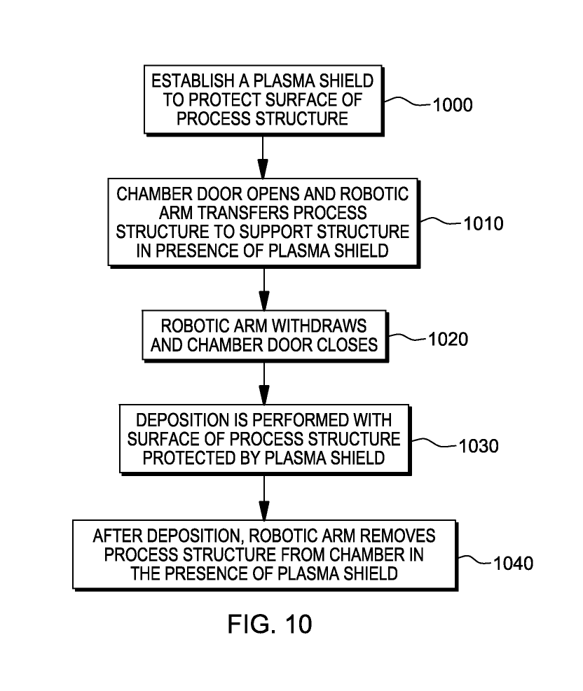

FIG. 10 depicts a process example, in accordance with one or more aspects of the present invention, for protecting a surface of a process structure, for instance, during transfer into a deposition chamber, and during deposition, and subsequent withdrawal of the process structure from the deposition chamber. The process begins by establishing a plasma shield over the surface of interest of the process structure to be protected 1000, for instance, in a manner such as described above in connection with FIGS. 2A-9B. This plasma shield may be established, in one embodiment, within the transfer chamber, for example, by appropriately configuring the robotic arm with a plasma-generating system such as disclosed herein. The deposition chamber isolation door is opened, and the robotic arm extends the process structure into the deposition chamber to transfer the process structure to a support structure, such as an electrostatic chuck support, within the deposition chamber 1010, which may include a separate plasma-generating system for generating a plasma shield around the support structure. This transfer into the deposition chamber and onto the support structure occurs in the presence of the plasma shield(s). The robotic arm then withdraws, and the deposition chamber isolation door is closed 1020. Deposition is performed, with the surface of the process structure protected by a plasma shield, as described herein 1030. After deposition processing, the isolation door is again opened, and the robotic arm removes the process structure from the deposition chamber; again, in one embodiment, in the presence of one or more plasma shields 1040. As noted, this transfer from the robotic arm (in the presence of a plasma shield) to the support structure and, in the reverse, the transfer from the support structure to the robotic arm (in the presence of a plasma shield), may utilize multiple plasma-generating systems, for instance, one associated with the support structure within the deposition chamber, or more generally, associated with the deposition chamber, and one associated with the robotic arm. Note also that as a variation, the plasma shield could be removed during the deposition processing, and then reestablished after deposition has completed.

As noted, various plasma-generating systems with different antenna structure configurations are presented herein, as well as various gas introduction configurations, and plasma-confinement approaches. Any of these configurations or approaches may be used in combination, depending on the implementation. Note that the plasma shield concept disclosed herein has the potential to eliminate particle add-on during transport and deposition of material onto a process structure, such as a mask wafer. Further, particles deposited as a result of the electrostatic interaction of the process structure and the electrostatic chuck support are eliminated from affecting the deposition of layers onto the surface of the process structure, which significantly enhances commercial viability of EUV lithography. Eliminating particles from the surface of the process structure as proposed herein would advantageously allow for the production of cleaner masks, reticles, etc. Further, the plasma shield concepts disclosed herein can be readily implemented as presented, without significantly affecting existing fabrication facility processing.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. An apparatus comprising:
a plasma-generating system configured to establish a plasma shield over a surface of a process structure to be protected; and
wherein the plasma shield comprises a plasma region and a plasma sheath over the surface of the process structure, the plasma sheath being disposed at least partially adjacent to the surface of the process structure, between the plasma region and the surface of the process structure, and wherein the plasma shield electrostatically inhibits negatively-charged particle contamination of the surface of the process structure to be protected.

2. The apparatus of claim 1, wherein the plasma shield negatively charges particles within the plasma shield.

3. The apparatus of claim 1, further comprising a support structure supporting the process structure, and wherein the plasma-generating system generates the plasma shield over the surface of the process structure to be protected, with the process structure supported by the support structure.

4. The apparatus of claim 3, wherein the support structure comprises an electrostatic chuck support, the electrostatic chuck support clamping electrostatically the process structure to the electrostatic chuck support.

5. The apparatus of claim 3, wherein the process structure comprises a mask, and the surface of the process structure to be protected is a surface of the mask.

6. The apparatus of claim 1, wherein the plasma-generating system comprises a plasma-generating antenna structure, the plasma-generating antenna structure being disposed, at least partially, along a periphery of the surface of the process structure to be protected.

7. The apparatus of claim 6, wherein the plasma-generating antenna structure is disposed, at least partially, at an elevation below the surface of the process structure to be protected.

8. The apparatus of claim 6, wherein the plasma-generating antenna structure comprises one or more plasma-generating coils disposed, at least partially, along the periphery of the surface of the process structure to be protected.

9. The apparatus of claim 6, wherein the plasma-generating antenna structure comprises a plurality of gas vents disposed, at least partially, within the plasma-generating antenna structure, the plurality of gas vents facilitating introduction of a gas in the vicinity of the process structure to facilitate establishing the plasma shield over the surface of the process structure to be protected.

10. The apparatus of claim 1, wherein the plasma-generating system further comprises a gas flow mechanism for establishing a gas flow across the surface of the process structure to be protected, the gas flow facilitating establishing of the plasma shield over the surface of the process structure to be protected.

11. The apparatus of claim 1, wherein the plasma-generating system further comprises a plasma-confining mechanism, the plasma-confining mechanism comprising at least one magnet disposed to facilitate generating the plasma shield over the surface of the process structure to be protected.

12. The apparatus of claim 11, wherein the plasma-confining mechanism comprises multiple permanent magnets, the multiple permanent magnets being disposed adjacent to a periphery of the surface of the process structure, and the multiple permanent magnets facilitating generating the plasma shield over the surface of the process structure to be protected by assisting in retaining electrons over the surface of the process structure.

13. The apparatus of claim 11, wherein the plasma-confining mechanism comprises multiple electromagnets, the multiple electromagnets being disposed adjacent to a periphery of the surface of the process structure, and the multiple electromagnets facilitating generating the plasma shield over the surface of the mask to be protected by assisting in retaining electrons over the surface of the process structure.

14. The apparatus of claim 1, further comprising a chamber, and wherein the plasma-generating system generates the plasma shield within the chamber.

15. The apparatus of claim 14, wherein the chamber comprises a deposition chamber, and wherein the plasma-generating system is configured to establish a localized plasma shield over the surface of the process structure to be protected within the deposition chamber.

16. The apparatus of claim 14, wherein the chamber comprises a deposition chamber facilitating deposition of a specified material onto the surface of the process structure to be protected, and wherein the plasma-generating system comprises a plasma-generating antenna structure, the plasma-generating antenna structure being fabricated, at least partially, of the specified material to be deposited onto the surface of the process structure.

17. A method comprising:
inhibiting particle contamination of a surface of a process structure to be protected, the inhibiting comprising:
generating a plasma shield over the surface of the process structure, the plasma shield comprising a plasma region and a plasma sheath over the surface of the process structure, wherein the plasma sheath is disposed, at least partially, adjacent to the surface of the process structure, between the plasma region and the surface of the process structure, and wherein the plasma shield facilitates negatively charging particles within the plasma shield, and electrostatically inhibits negatively-charged particle contamination of the surface of the process structure.

18. The method of claim 17, wherein the inhibiting further comprises providing the plasma shield over the surface of the process structure during transfer of the process structure.

19. The method of claim 17, wherein the inhibiting further comprises providing the plasma shield over the surface of the process structure during transfer of the process structure into or out of a process chamber.

20. The method of claim 17, wherein the inhibiting further comprises providing the plasma shield over the surface of the process structure to be protected, while transferring the process structure from a first chamber to a second chamber of a fabrication facility.

21. The method of claim 17, wherein the inhibiting further comprises providing the plasma shield over the surface of the process structure within a deposition chamber.

22. The method of claim 21, wherein the generating comprises establishing a localized plasma shield over the surface of the process structure within the deposition chamber, wherein the localized plasma shield resides within a portion of the deposition chamber in a localized region overlying the surface of the process structure, the localized plasma shield overlying the surface of the process structure simultaneous with performing deposition on the surface of the process structure.

23. The method of claim 17, wherein the generating comprises disposing a plasma-generating antenna structure, at least partially, along a periphery of the surface of the process structure to be protected, the plasma-generating antenna structure facilitating generating of the plasma shield over the surface of the process structure.

24. The method of claim 23, wherein the plasma-generating antenna structure further comprises a plurality of gas vents disposed, at least partially, within the plasma-generating antenna structure, and wherein the method further comprises introducing a gas in the vicinity of the process structure, through the plurality of gas vents of the plasma-generating antenna structure, the gas facilitating establishing of the plasma shield over the surface of the process structure to be protected.

25. The method of claim 17, wherein the generating further comprises establishing a gas flow across the surface of the process structure to be protected, the gas flow facilitating establishing of the plasma shield over the surface of the process structure.

26. The method of claim 17, wherein the generating further comprises providing a plasma-confining mechanism, the plasma-confining mechanism comprising at least one magnet disposed to facilitate generating the plasma shield over the surface of the process structure to be protected.
